(19) United States
(12) Patent Application Publication
(10) Pub. No.: US 2026/0188196 A1
(43) Pub. Date: Jul. 2, 2026

(54) Display Apparatus

(71) Applicant: LG Display Co., Ltd., Seoul (KR)

(72) Inventors: Hyunjik Bae, Paju-si (KR); Jungseop Yoon, Paju-si (KR); ByungJune Mun, Paju-si (KR)

(21) Appl. No.: 19/411,052

(22) Filed: Dec. 5, 2025

(30) Foreign Application Priority Data
Dec. 30, 2024 (KR) 10-2024-0201154

(51) Int. Cl. G09G 3/32; H10H 20/855

(52) U.S. Cl. CPC G09G 3/32; H10H 20/855; G09G 2310/0267; G09G 2320/028; G09G 2320/068; G09G 2330/021

(57) ABSTRACT

Embodiments of the present disclosure are directed to a display apparatus independently controlling viewing angles. The display apparatus may include a display area including a first region and a second region independently controlling viewing angles, and a gate driving circuit disposed in a non-display area outside of the display area. The gate driving circuit may include a first switching part connected to a first subpixel of the first region, and a second switching part connected to a second subpixel of the second region. Each of the first switching part and the second switching part selectively may output the first light emission control signal and the second light emission control signal in response to a first viewing angle control signal and a second viewing angle control signal.

### CROSS-REFERENCE TO RELATED APPLICATION

The present application claims the priority to Republic of Korea Patent Application No. 10-2024-0201154 filed on December 30, 2024, which is incorporated by reference in its entirety.

### BACKGROUND

### FIELD

The present disclosure relates to a display apparatus capable of controlling a viewing angle.

### Discussion of the Related Art

The display apparatuses can be used in various electronic devices.

Among the display apparatuses installed in automobiles, the display apparatus disposed in front of the passenger seat needs to limit the driver's field of view depending on the driver's driving situation.

The display apparatuses need to limit the viewing angle according to user needs for privacy and information protection.

The display apparatuses may use security films to limit the viewing angle of the displayed image. However, security films significantly reduce the brightness of the display apparatus, and the viewing angle is limited, which can cause inconvenience to the user.

### SUMMARY

Accordingly, the present disclosure is directed to providing a display apparatus that substantially obviate one or more problems due to limitations and disadvantages of the related art.

In one or more embodiments, the present disclosure provides a display apparatus capable of independently controlling a viewing angle in multiple areas.

Additional advantages and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and claims hereof as well as the appended drawings.

The display apparatus according to one or more embodiments of the present disclosure includes a display area including a first display area and a second display area independently controlling viewing angles, and a gate driving circuit disposed in a non-display area outside of the display area, wherein each of a plurality of subpixels disposed in the display area includes a driving transistor, a first light emitting element, a second light emitting element, a first light emission control transistor connecting the driving transistor to the first light emitting element in response to a first light emission control signal, and a second light emission control transistor connecting the driving transistor to the second light emitting element in response to a second light emission control signal, wherein the gate driving circuit includes a first switching part connected to a first subpixel of the first display area; and a second switching part connected to a second subpixel of the second display area, and wherein each of the first switching part and the second switching part selectively outputs the first light emission control signal and the second light emission control signal in response to a first viewing angle control signal and a second viewing angle control signal.

The display apparatus according to one or more embodiments of the present disclosure may include a first display area including a first subpixel and a second display area including a second subpixel. The first subpixel may include a first light emitting element emitting light of a first color, a first lens of a first shape overlapping the first light emitting element in a cross-sectional view of the display apparatus, a second light emitting element emitting light of the first color, and a second lens of a second shape overlapping the second light emitting element in the cross-sectional view. The second subpixel may include a third light emitting element emitting light of the first color, a third lens of the first shape overlapping the third light emitting element in the cross-sectional view, a fourth light emitting element emitting light of the first color, and a fourth lens of the second shape overlapping the fourth light emitting element in the cross-sectional view. When the first display area is in a first mode, the first light emitting element may be in a first state and the second light emitting element is in a second state. When the first display area is in a second mode, the first light emitting element may be in the second state and the second light emitting element is in the first state. When the second display area is in the first mode, the third light emitting element may be in the first state and the fourth light emitting element is in the second state. When the second display area is in the second mode, the third light emitting element may be in the second state and the fourth light emitting element is in the first state.

The first display area may emit light over a first viewing angle in a first direction, when the first display area is in the first mode. The first display area may emit light over a second viewing angle in the first direction that is less than the first viewing angle, when the first display area is in the second mode. The second display area may emit light over the first viewing angle in the first direction, when the second display area is in the first mode. The second display area may emit light over the second viewing angle in the first direction, when the second display area is in the second mode.

The first lens may transmit light over the first viewing angle in the first direction, when the first display area is in the first mode. The second lens may transmit light over the second viewing angle in the first direction, when the first display area is in the second mode. The third lens may transmit light over the first viewing angle in the first direction, when the second display area is in the first mode. The fourth lens may transmit light over the second viewing angle in the first direction, when the second display area is in the second mode.

It is to be understood that both the foregoing general description and the following detailed description of the present disclosure are exemplary and explanatory and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic diagram illustrating a display apparatus configuration according to one or more embodiments of the present disclosure.

FIG. 2 is a cross-sectional view schematically showing the structure of a display panel according to one or more embodiments of the present disclosure.

FIG. 3 is a schematic diagram illustrating a subpixel configuration according to one or more embodiments of the present disclosure.

FIGS. 4A and 4B are diagrams illustrating the structure of the first and second light control elements according to one or more embodiments of the present disclosure.

FIG. 5 is a schematic diagram illustrating a plurality of areas in which a viewing angle can be independently controlled in the display apparatus according to one or more embodiments of the present disclosure.

FIG. 6 is an equivalent circuit diagram illustrating a subpixel configuration according to one or more embodiments of the present disclosure.

FIG. 7 is a diagram illustrating the driving waveform of the subpixel illustrated in FIG. 6.

FIG. 8 is a schematic diagram illustrating a gate driving circuit configuration according to one or more embodiments of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present disclosure are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically. The embodiments of the present disclosure may be carried out independently from each other, or may be carried out together in a co-dependent relationship.

Hereinafter, the embodiments of the present disclosure will be described with reference to the accompanying drawings. Since a scale of each of elements shown in the accompanying drawings is different from an actual scale for convenience of description, the present disclosure is not limited to the shown scale. Further, all the components of each display apparatus, display device, and display panel according to all embodiments of the present disclosure are operatively coupled and configured.

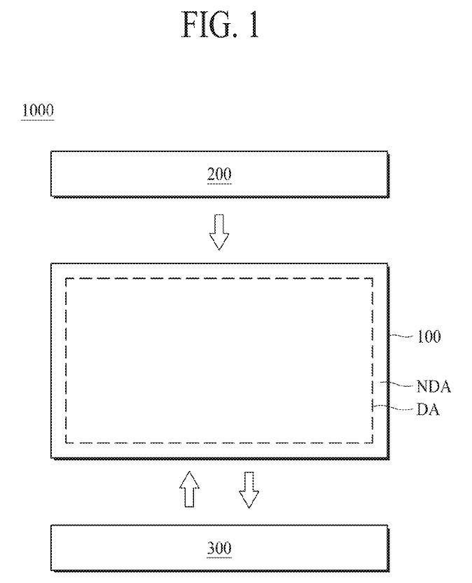

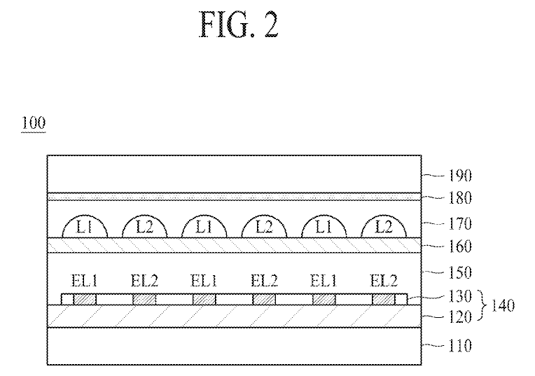

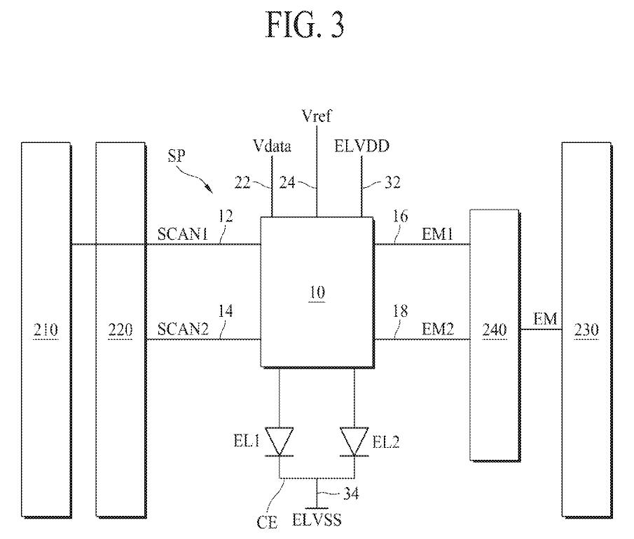

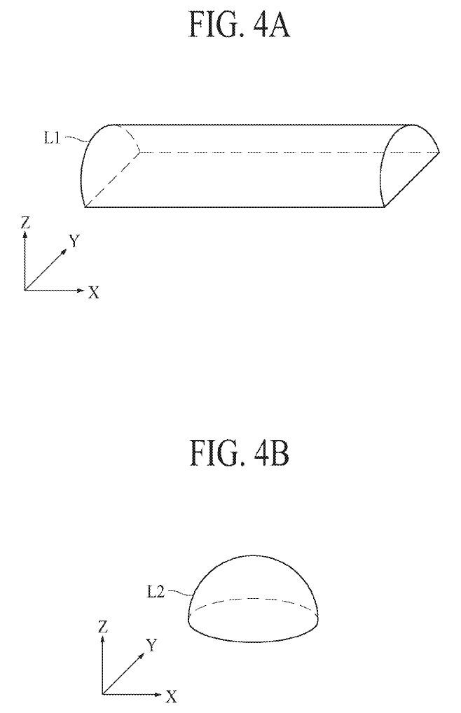

FIG. 1 is a schematic diagram illustrating a configuration of a display apparatus according to one or more embodiments, FIG. 2 is a cross-sectional diagram schematically illustrating a structure of a display panel according to one or more embodiments, FIG. 3 is a schematic diagram illustrating a subpixel configuration according to one or more embodiments, and FIGS. 4A and 4B are diagrams illustrating structures of first and second light control elements according to one or more embodiments.

A display apparatus 1000 according to one or more embodiments may provide both a display function for displaying an image and a touch sensing function for sensing the presence or absence of a user's touch and/or touch coordinates.

The display apparatus 1000 according to one or more embodiments may be an electro-luminescent display apparatus or a micro light emitting diode display apparatus including a touch sensor. The electro-luminescent display apparatus including a touch sensor may be an organic light emitting diode (OLED) display apparatus, a quantum-dot light emitting diode (QD) display apparatus, or an inorganic light emitting diode (ILD) display apparatus.

Referring to FIG. 1, the display apparatus 1000 may include a display panel 100, a display driving circuit 200 that drives the display panel 100, and a touch sensing circuit 300 that drives and senses a touch sensor array built into the display panel 100. The display apparatus 1000 may further include a power management circuit that generates and supplies a plurality of power voltages required for the operation of the display panel 100, the display driving circuit 200, and the touch sensing circuit 300.

The display panel 100 may be a rigid display panel or a flexible display panel capable of changing shape, such as a foldable, bendable, rollable, or stretchable display panel.

The display panel 100 may include a display area DA for displaying an image, and a non-display area NDA, which is a bezel area disposed on the outer edge surrounding the display area DA. The display panel 100 may further include a touch sensor array that is disposed in the display area DA and senses a user's touch.

The display panel 100 can display an image using the display area DA in which a plurality of subpixels are disposed in a matrix form. The pixel matrix of the display area DA may include a plurality of row lines composed of a plurality of subpixels disposed in a first direction X and a plurality of column lines composed of a plurality of subpixels disposed in a second direction Y. The display panel 100 may include a plurality of signal lines including a plurality of gate lines, a plurality of data lines, a plurality of power lines, or the like, connected to a plurality of subpixels.

The plurality of subpixels may include a red subpixel that emits red light, a green subpixel that emits green light, and a blue subpixel that emits blue light. The plurality of subpixels may further include a white subpixel that emits white light. A unit pixel may include at least two subpixels.

The display driving circuit 200 may include a data driving circuit that supplies data voltages to a plurality of data lines of the display panel 100, a gate driving circuit that supplies gate signals to a plurality of gate lines, a timing controller that controls the operations of the data driving circuit and the gate driving circuit, or the like.

The touch sensing circuit 300 may include a touch driving circuit that supplies a touch driving signal to a touch sensor array built into the display panel 100 and receives a readout signal from the touch sensor array, and generates sensing data. The touch sensing circuit 300 may further include a touch controller that detects the presence or absence of a touch and the touch coordinate position based on the sensing data supplied from the touch driving circuit.

The touch sensor array may use a self-capacitance method that senses changes in self-capacitance according to touch, or a mutual-capacitance method that senses changes in mutual-capacitance according to touch.

The display panel 100 according to one or more embodiments may be capable of controlling a viewing angle according to a viewing angle mode. The display area DA of the display panel 100 may display an image in a first viewing angle mode in which a viewing angle in a first direction is relatively wide, or in a second viewing angle mode in which a viewing angle in the first direction is narrower than the first viewing angle mode. The first viewing angle mode may be expressed as a wide viewing angle mode or a share mode. The second viewing angle mode may be expressed as a narrow viewing angle mode or a privacy mode. The display area DA of the display panel 100 may be driven in a switchable privacy mode (SPM) in which the share mode and the privacy mode can be switched.

Referring to FIG. 2, the display panel 100 according to one or more embodiments may include a pixel array 140. The pixel array 140 may include a circuit element layer 120 including a plurality of transistors and a plurality of signal lines, or the like, disposed on a substrate 110 and a light emitting element layer 130 including a plurality of light emitting elements EL1 and EL2 disposed on the circuit element layer 120. The display panel 100 may further include an encapsulation layer 150 disposed on the pixel array 140 to seal the light emitting element layer 130. The display panel 100 may further include a touch sensor array 160 including a plurality of sensor electrodes disposed on the encapsulation layer 150, and a light control array 170 including a plurality of light control elements L1 and L2 disposed on the touch sensor array 160. The display panel 100 may further include a cover substrate 190 bonded to the light control array 170 by an optical clear adhesive (OCA) 180.

The touch sensor array 160 according to one or more embodiments may include a sensor electrode, a dummy electrode, and a black matrix arranged to overlap with a non-emission region of the first and second light emitting elements EL1 and EL2. At least one of the sensor electrode, the dummy electrode, and the black matrix according to one or more embodiments may overlap with an end portion of the light control elements L1 and L2 to act as a barrier that blocks light, thereby preventing light leakage due to light leakage or reflected light. At least one of the sensor electrode, the dummy electrode, and the black matrix according to one or more embodiments may not overlap with an end portion of a first light control element L1 for a wide viewing angle, thereby preventing a limitation of the wide viewing angle.

Referring to FIGS. 2 and 3, a subpixel SP according to one or more embodiments capable of controlling a viewing angle may include a first light emitting element EL1, a second light emitting element EL2, and a pixel circuit 10 that drives the first and second light emitting elements EL1 and EL2 in a time-division manner according to a viewing angle mode. The subpixel SP may further include a first light control element L1 overlapped on the first light emitting element EL1, and a second light control element L2 overlapped on the second light emitting element EL2.

According to one or more embodiments, the subpixel SP may drive the first light emitting element EL1 in a first viewing angle mode and may emit light having a first viewing angle through the first light control element L1. The subpixel SP may drive the second light emitting element EL2 in a second viewing angle mode and may emit light having a second viewing angle narrower than the first viewing angle through the second light control element L2.

Referring to FIG. 3, a gate driving circuit according to one or more embodiments may include a plurality of scan driving circuits 210 and 220, a light emission control driving circuit 230, and a switching circuit 240. The gate driving circuit may be disposed in at least one of a plurality of non-display areas NDA of the display panel 100.

According to one or more embodiments, the subpixel SP may receive a data voltage Vdata from a data driving circuit via one data line 22. The subpixel SP may receive first and second scan signals SCAN1 and SCAN2 from first and second scan driving circuits 210 and 220 via first and second gate lines 12 and 14.

The light emission control driving circuit 230 may output a light emission control signal EM, and the switching circuit 240 may selectively output the light emission control signal EM to third and fourth gate lines 16 and 18 as the first and second light emission control signals EM1 and EM2 according to first and second viewing angle control signals SH and PR.

The subpixel SP may receive the first light emission control signal EM1 from the switching circuit 240 through the third gate line 16 and may receive the second light emission control signal EM2 through the fourth gate line 18.

The subpixel SP may selectively drive the first light emitting element EL1 and the second light emitting element EL2 in response to the first and second light emission control signals EM1 and EM2.

According to one or more embodiments, the subpixel SP may be supplied with a high-potential power voltage ELVDD from a power management circuit through a first power line 32, a low-potential power voltage ELVSS through a cathode electrode CE and a second power line 34, and a reference voltage Vref through a reference line 24.

Referring to FIG. 4A, the first light control element L1 may have a half-cylindrical lens structure that is elongated in the first direction X, but is not limited to this lens structure. Referring to FIG. 4B, the second light control element L2 may have a half-spherical lens structure, but is not limited to this lens structure. In one or more embodiments, the first light control element L1 and the second light control element L2 may control (limit) the viewing angle in the first direction X differently, and control (limit) the viewing angle in the second direction Y equally.

According to one or more embodiments, the first and second light control elements L1 and L2 may be formed of a fluid material, a semi-fluid material, or a solid. The material and configuration of the first and second light control elements L1 and L2 are not limited to the examples described above. In addition, depending on the case, the first and second light control elements L1 and L2 may be referred to as a light control layer, a light control configuration, a lens, or a viewing angle control unit, but are not limited to these terms.

In FIGS. 4A and 4B, the first direction X may represent the left-right direction (horizontal direction) of the display panel 100, the second direction Y may represent the up-down direction (vertical direction) of the display panel 100, and the third direction Z may represent the front-back direction (thickness direction) of the display panel 100.

In the first viewing angle mode, each subpixel SP of the display panel 100 may drive the first light emitting element EL1 and may not limit the path of light emitted from the first light emitting element EL1 to within a specific cut-off angle in the first direction X through the first light control element L1, thereby providing light having a wide viewing angle.

In the second viewing angle mode, each subpixel SP of the display panel 100 may drive the second light emitting element EL2 and provide light having a narrow viewing angle by limiting the path of light emitted from the second light emitting element EL2 to within a specific cut-off angle in the first direction X through the second light control element L2.

The first light control element L1 and the second light control element L2 may control the light propagation path in the second direction Y to a narrow viewing angle by limiting it to within the cut-off angle. Accordingly, in one or more embodiments, when the display apparatus 1000 is applied to a vehicle, the image displayed on the display apparatus 1000 may be prevented from being reflected by the windshield of the vehicle and obstructing the driver's view.

At least one of a low-temperature poly silicon (LTPS) transistor using a low-temperature poly silicon semiconductor and an oxide transistor using a metal-oxide semiconductor may be applied to a plurality of transistors disposed in the display area DA of the display panel 100 and the non-display area NDA including a gate driving circuit. In one or more embodiments, the display panel 100 may be configured so that LTPS transistors and oxide transistors coexist in order to reduce power consumption.

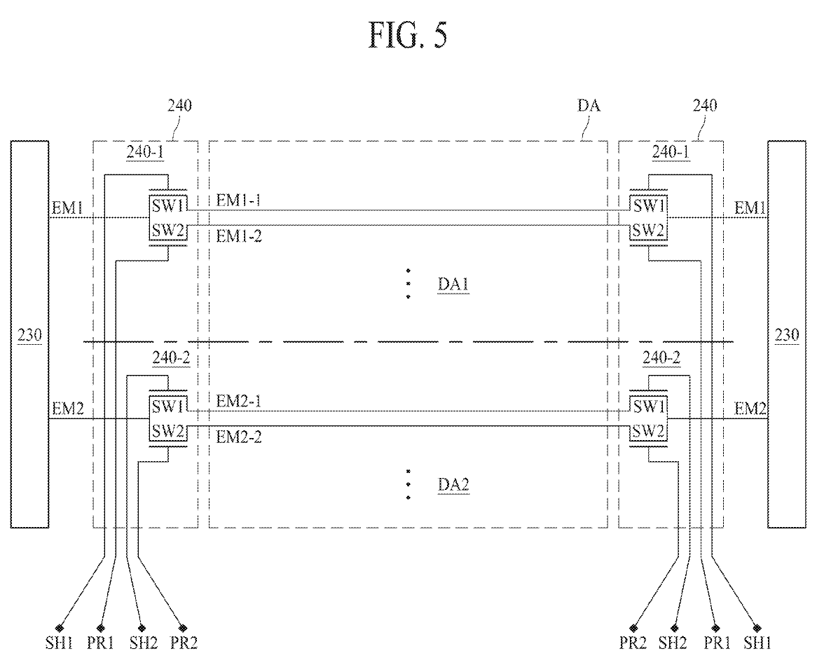

FIG. 5 is a schematic diagram illustrating a plurality of areas in which a viewing angle can be independently controlled in the display apparatus according to one or more embodiments of the present disclosure.

Referring to FIG. 5, the display apparatus according to one or more embodiments may include a first display area DA1 and a second display area DA2 capable of independently controlling a viewing angle. The first and second display areas DA1 and DA2 may be divided in a vertical direction (Y-axis direction).

The gate driving circuit according to one or more embodiments may include a first switching circuit 240-1 connected to the first display area DA1 and a second switching circuit 240-2 connected to the second display area DA2.

The first switching circuit 240-1 may include first and second switching elements SW1 and SW2 that selectively output first and second light emission control signals EM1-1 and EM1-2 to the first display area DA1 in response to first and second viewing angle control signals SH1 and PR1.

The second switching circuit 240-2 may include first and second switching elements SW1 and SW2 that selectively output first and second light emission control signals EM2-1 and EM2-2 to the second display area DA2 in response to first and second viewing angle control signals SH2 and PR2.

Each of the subpixels of the first display area DA1 may provide a wide viewing angle or a narrow viewing angle through the first or second light control element L1 or L2 by selectively driving the first and second light emitting elements EL1 and EL2 in response to the first and second light emission control signals EM1-1 and EM1-2.

Each of the subpixels of the second display area DA2 may provide a wide viewing angle or a narrow viewing angle through the first or second light control element L1 or L2 by selectively driving the first and second light emitting elements EL1 and EL2 in response to the first and second light emission control signals EM2-1 and EM2-2.

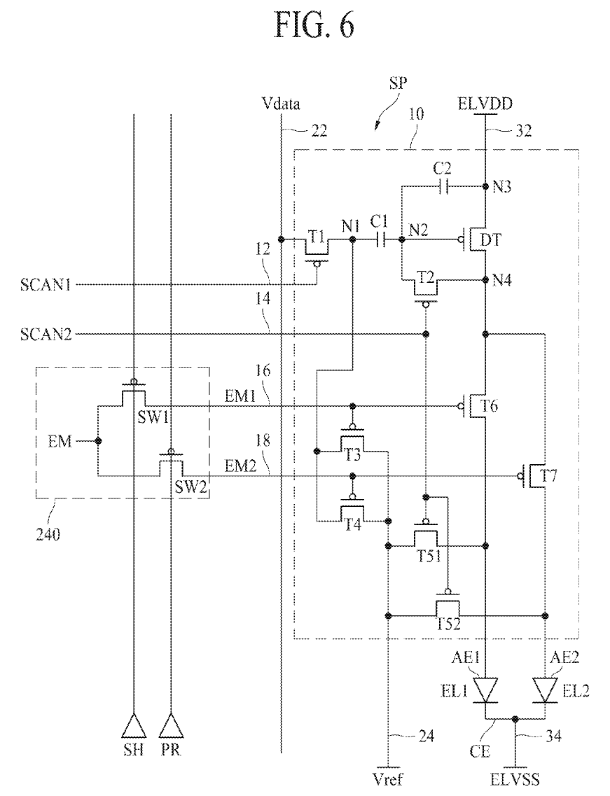

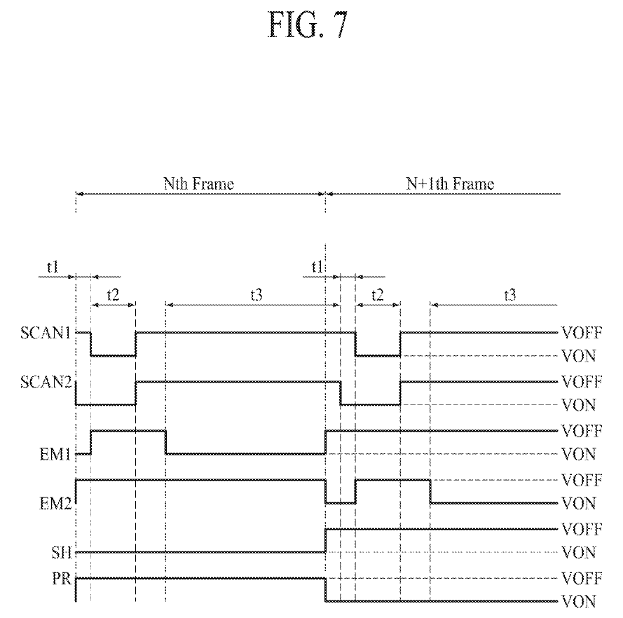

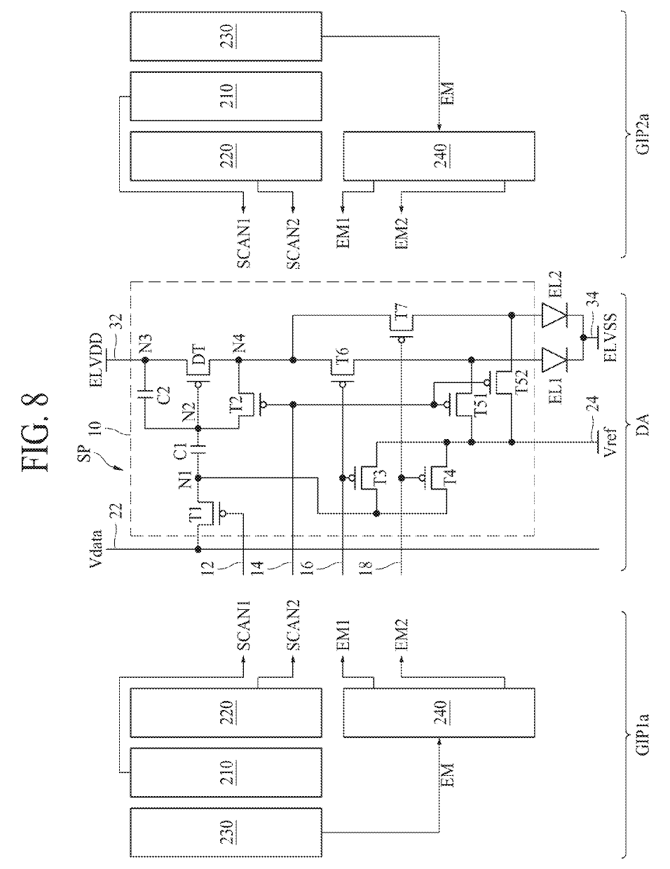

FIG. 6 is an equivalent circuit diagram illustrating a subpixel configuration according to one or more embodiments of the present disclosure, FIG. 7 is a diagram illustrating a driving waveform of the subpixel illustrated in FIG. 6, and FIG. 8 is a diagram schematically illustrating a gate driving circuit configuration according to one or more embodiments of the present disclosure.

Referring to FIG. 6, a subpixel SP may include first and second light emitting elements EL1 and EL2 and a pixel circuit 10 that time-divisionally drives the first and second light emitting elements EL1 and EL2. In one or more embodiments, the pixel circuit 10 may include a driving transistor DT, a plurality of switching transistors T1 to T7, and a plurality of capacitors C1 and C2, but is not limited to this configuration.

The pixel circuit 10 may receive a first scan signal SCAN1 from a first scan driving circuit 210 through a first gate line 12, and may receive a second scan signal SCAN2 from a second scan driving circuit 220 through a second gate line 14.

The pixel circuit 10 may receive the first and second light emission control signals EM1 and EM2 from the switching circuit 240 through the third and fourth gate lines 16 and 18.

The switching circuit 240 may include first and second switching elements SW1 and SW2 that output the light emission control signal EM as one of the first and second light emission control signals EM1 and EM2 in response to the first and second viewing angle control signals SH and PR.

Referring to FIG. 8, the gate driving circuit may include first and second gate driving circuits GIP1a and GIP1b disposed in non-display areas NDA on both sides of the display area DA, respectively. Each of the first and second gate driving circuits GIP1a and GIP1b may include a first scan driving circuit 210, a second scan driving circuit 220, a light emission control driving circuit 230, and a switching circuit 240.

The pixel circuit 10 may receive a data voltage Vdata from a data driving circuit through a data line 22. The pixel circuit 10 can receive a high-potential power voltage ELVDD from a power management circuit through a first power line 32, a low-potential power voltage ELVSS through the second power line 34 and the cathode electrode (common electrode) CE, and a reference voltage Vref through a reference line 24.

In one or more embodiments, the second light emitting element EL2 may include a plurality of light emitting elements. For example, the second light emitting element EL2 may include a 2-1 light emitting element and a 2-2 light emitting element. In this case, the 2-1 light emitting element and the 2-2 light emitting element may be connected in parallel. According to one or more embodiments, the 2-1 light emitting element and the 2-2 light emitting element may have a common anode formed therein, but the present disclosure is not limited thereto. According to one or more embodiments, the second light emitting element EL2 may include three or more light emitting elements.

Referring to FIG. 7, the subpixel SP may be driven to include an initialization period t1, a sampling and writing period t2, and a light emitting period t3 for each of the Nth and (N+1)th frame periods. For convenience of explanation, in FIG. 7, the Nth frame period may represent any one frame period in the first viewing angle mode (in which the first viewing angle control signal SH has a gate-on voltage VON), and the (N+1)th frame period may represent any one frame period in the second viewing angle mode (in which the second viewing angle control signal PR has a gate-on voltage VON).

Each of the driving transistor DT and the plurality of switching transistors T1 to T7 of the pixel circuit 10 may include a gate electrode, a source electrode, and a drain electrode. Since the source electrode and the drain electrode are not fixed and can be changed depending on the voltage and current direction applied to the gate electrode, any one of the source electrode and the drain electrode may be expressed as a first electrode, and the other may be expressed as a second electrode. The driving transistor DT and the plurality of switching transistors T1 to T7 of the pixel circuit 10 may use at least one of a polysilicon semiconductor, an amorphous silicon semiconductor, and an oxide semiconductor, and may use P type or N type, or a mixture of P type and N type.

The first and second light emitting elements EL1 and EL2 may have anode electrodes AE1 and AE2 individually connected to the sixth and seventh switching transistors T6 and T7, a cathode electrode CE supplied with a low-potential power voltage ELVSS from a second power line 34, and a light emitting layer between the anode electrodes AE1 and AE2 and the cathode electrode CE. When a driving current is supplied from a driving transistor DT through the sixth and seventh switching transistors T6 and T7, respectively, the first and second light emitting elements EL1 and EL2 are injected with electrons from the cathode electrode CE into the light emitting layer, and holes from the anode electrodes AE1 and AE2 are injected into the light emitting layer, so that a fluorescent or phosphorescent material emits light through recombination of electrons and holes in the light emitting layer, thereby emitting light having a brightness proportional to the current value of the driving current.

The second node N2 connected to the gate electrode of the driving transistor DT may be connected to a first capacitor C1, a third node N3 connected to the first electrode of the driving transistor DT may be connected to the first power line 32 supplying a high-potential power voltage ELVDD, and a fourth node N4 connected to the second electrode of the driving transistor DT may be commonly connected to the second, sixth, and seventh switching transistors T2, T6, and T7. A second capacitor C2 may further be connected between the gate electrode of the driving transistor DT and the first power line 32 to stably maintain the gate voltage of the driving transistor DT.

The driving transistor DT may drive the first light emitting element EL1 through the sixth switching transistor T6 or the second light emitting element EL2 through the seventh switching transistor T7. The driving transistor DT may control the light emitting intensity of the first light emitting element EL1 or the light emitting intensity of the second light emitting element EL2 by controlling the driving current according to the driving voltage charged in the first capacitor C1.

A first capacitor C1 may be connected between a first node N1 connected to a second electrode of a first switching transistor T1 and a second node N2 connected to a gate electrode of a driving transistor DT, and may charge the driving voltage corresponding to a data voltage Vdata. The first capacitor C1 can hold the charged driving voltage during the light emitting period t3 in which the first switching transistor T1 is turned off, and supply the same to the driving transistor DT.

The first switching transistor T1 may be turned on or off in response to the first scan signal SCAN1 of the first gate line 12. The first switching transistor T1 may supply a data voltage Vdata supplied through the data line 22 to the first electrode of the first capacitor C1 through the first node N1 during the sampling and writing period t2 in which the first scan signal SCAN1 has a gate-on voltage VON. The first switching transistor T1 may be turned off during the initialization period t1, a period between the sampling and writing period t2 and the light emitting period t3, and the light emitting period t3 in which the first scan signal SCAN1 has a gate-off voltage VOFF.

The second, 5-1, and 5-2 switching transistors T2, T51, and T52 may be turned on or off in response to the second scan signal SCAN2 supplied to the second gate line 14. The second, 5-1, and 5-2 switching transistors T2, T51, and T52 may be turned on during the initialization period t1 and the sampling and writing period t2 in which the second scan signal SCAN2 has the gate-on voltage VON, and may be turned off during the light emitting period t3 and during a period between the sampling and writing period t2 and the light emitting period t3 in which the second scan signal SCAN2 has the gate-off voltage VOFF.

The second switching transistor T2 may connect the gate electrode and the second electrode of the driving transistor DT during the initialization period t1 and the sampling and writing period t2 in response to the second scan signal SCAN2, thereby connecting the driving transistor DT in a diode structure. The second switching transistor T2 may compensate for the threshold voltage (Vth) of the driving transistor DT by charging the first capacitor C1 with the threshold voltage (Vth). Accordingly, the first capacitor C1 may charge the data voltage for which the threshold voltage (Vth) of the driving transistor DT is compensated.

The 5-1 and 5-2 switching transistors T51 and T52 may supply a reference voltage Vref supplied through the reference line 24 to the anode electrodes AE1 and AE2 of the first and second light emitting elements EL1 and EL2, respectively, during the initialization period t1 and the sampling and writing period t2 in response to the second scan signal SCAN2.

The third switching transistor T3 may be turned on or off during the Nth frame as the driving period of the first viewing angle mode and may be turned off during the (N+1)th frame as the driving period of the second viewing angle mode in response to the first light emission control signal EM1 supplied to the third gate line 16. The third switching transistor T3 may be turned on during the initialization period t1 and the light emitting period t3 of the Nth frame as the driving period of the first viewing angle mode in which the first light emission control signal EM1 has the gate-on voltage VON. The third switching transistor T3 may be turned off during the sampling and writing period t2 and during a period between the sampling and writing period t2 and the light emitting period t3 of the Nth frame as the driving period of the first viewing angle mode, and during the (N+1)th frame as the driving period of the second viewing angle mode in which the first light emission control signal EM1 has the gate-off voltage VOFF. The third switching transistor T3 may supply the reference voltage Vref supplied through the reference line 24 to the first electrode of the first capacitor C1 during the initialization period t1 and the light emitting period t3 of the Nth frame as the driving period of the first viewing angle mode in response to the first light emission control signal EM1.

The fourth switching transistor T4 may be turned on or turned off during the (N+1)th frame as the driving period of the second viewing angle mode and may be turned off during the Nth frame as the driving period of the first viewing angle mode in response to the second light emission control signal EM2 supplied to the fourth gate line 18. The fourth switching transistor T4 may be turned on during the initialization period t1 and the light emitting period t3 of the (N+1)th frame as the driving period of the second viewing angle mode in which the second light emission control signal EM2 has the gate-on voltage VON. The fourth switching transistor T4 may be turned off during the sampling and writing period t2 and during the period between the sampling and writing period t2 and the

light emitting period t3 of the (N+1)th frame as the driving period of the second viewing angle mode, and during the Nth frame as the driving period of the first viewing angle mode in which the second light emission control signal EM2 has the gate-off voltage VOFF. The fourth switching transistor T4 may supply the reference voltage Vref supplied through the reference line 24 to the first electrode of the first capacitor C1 during the initialization period t1 and the light emitting period t3 of the (N+1)th frame as the driving period of the second viewing angle mode in response to the second light emission control signal EM2.

The sixth switching transistor T6 as a first light emission control transistor T6 may be turned on or turned off during the Nth frame as the driving period of the first viewing angle mode and may be turned off during the N+1th frame as the driving period of the second viewing angle mode in response to the first light emission control signal EM1 supplied to the third gate line 16. The sixth switching transistor T6 may be turned on during the initialization period t1 and the light emitting period t3 of the Nth frame as the driving period of the first viewing angle mode in which the first light emission control signal EM1 has the gate-on voltage VON. The sixth switching transistor T6 may be turned off during the sampling and writing period t2 and during a period between the sampling and writing period t2 and the emission period t3 of the Nth frame as the driving period of the first viewing angle mode and during the (N+1)th frame as the driving period of the second viewing angle mode in which the first light emission control signal EM1 has the gate-off voltage VOFF. The sixth switching transistor T6 may connect the driving transistor DT to the first light emitting element EL1 during the initialization period t1 and the light emitting period t3 of the Nth frame as the driving period of the first viewing angle mode in response to the first light emission control signal EM1.

During the light emitting period t3 of the Nth frame as the driving period of the first viewing angle mode, the driving transistor DT may drive the first light emitting element EL1 through the sixth switching transistor T6. Accordingly, the subpixel SP may provide light of the first viewing angle through the first light emitting element EL1 and the first light control element L1 shown in FIG. 4A.

The seventh switching transistor T7 as a second light emission control transistor T7 may be turned on or turned off during the (N+1)th frame as the driving period of the second viewing angle mode and may be turned off during the Nth frame as the driving period of the first viewing angle mode in response to the second light emission control signal EM2 supplied to the fourth gate line 18. The seventh switching transistor T7 may be turned on during the initialization period t1 and the light emitting period t3 of the (N+1)th frame as the driving period of the second viewing angle mode in which the second light emission control signal EM2 has the gate-on voltage VON. The seventh switching transistor T7 may be turned off during the sampling and writing period t2 and the period between the sampling and writing period t2 and the light emitting period t3 of the (N+1)th frame as the driving period of the second viewing angle mode and during the Nth frame as the driving period of the first viewing angle mode in which the second light emission control signal EM2 has the gate-off voltage VOFF. The seventh switching transistor T7 may connect the driving transistor DT to the second light emitting element EL2 during the initialization period t1 and the light emitting period t3 of the (N+1)th frame as the driving period of the second viewing angle mode in response to the second light emission control signal EM2.

During the light emitting period t3 of the (N+1)th frame as the driving period of the second viewing angle mode, the driving transistor DT may drive the second light emitting element EL2 through the seventh switching transistor T7. Accordingly, the subpixel SP may provide light of the second viewing angle through the second light emitting element EL2 and the second light control element L2 shown in FIG. 4B.

As described above, the display apparatus according to one or more embodiments of the present disclosure can control the viewing angle according to the user's needs by separately driving the light emitting elements of each subpixel, and can independently control the viewing angle of each of a plurality of areas by selectively outputting the first and second light emission control signals.

The display apparatus according to one or more embodiments of the present disclosure can adjust a ratio or a size of the wide viewing angle area and the narrow viewing angle area by independently controlling the viewing angles of a plurality of areas in a display area to be wide or narrow viewing angles, thereby providing a user with an image of a desired size at a desired viewing angle.

The above-described feature, structure, and effect of the present disclosure are included in one or more embodiments of the present disclosure, but are not limited to only the one or more embodiments. Furthermore, the feature, structure, and effect described in one or more embodiments of the present disclosure may be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the scope of the present disclosure includes those represented by the following claims, and all changes or modifications derived from the meaning, range and equivalent concept of the claims should be interpreted as being included in the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display apparatus, comprising:
a display area including a first display area and a second display area independently controlling viewing angles; and
a gate driving circuit disposed in a non-display area outside of the display area,
wherein each of a plurality of subpixels disposed in the display area includes:
a driving transistor;
a first light emitting element;
a second light emitting element;
a first light emission control transistor connecting the driving transistor to the first light emitting element in response to a first light emission control signal; and
a second light emission control transistor connecting the driving transistor to the second light emitting element in response to a second light emission control signal,
wherein the gate driving circuit includes:
a first switching part connected to a first subpixel of the first display area; and
a second switching part connected to a second subpixel of the second display area, and
wherein each of the first switching part and the second switching part is configured to selectively output the first light emission control signal and the second light emission control signal in response to a first viewing angle control signal and a second viewing angle control signal.

2. The display apparatus of claim 1, wherein each of the plurality of subpixels comprises:
a first lens disposed on the first light emitting element; and
a second lens disposed on the second light emitting element,
wherein the first lens controls a viewing angle in a first direction to a wide viewing angle, and
wherein the second lens controls the viewing angle in the first direction to a narrow viewing angle smaller than a specific angle.

3. The display apparatus of claim 1, wherein:
the first display area provides a wide viewing angle when the first light emitting element is driven in response to the first light emission control signal, and
the first display area provides a narrow viewing angle when the second light emitting element is driven in response to the second light emission control signal.

4. The display apparatus of claim 1, wherein:
the second display area provides a wide viewing angle when the first light emitting element is driven in response to the first light emission control signal, and
the second display area provides a narrow viewing angle when the second light emitting element is driven in response to the second light emission control signal.

5. The display apparatus of claim 1, wherein the first display area and the second display area are disposed separately in a second direction.

6. The display apparatus of claim 1, wherein the gate driving circuit comprises:
a first scan driving circuit configured to supply a first scan signal to a corresponding subpixel among the plurality of subpixels through a first gate line;
a second scan driving circuit configured to supply a second scan signal to a corresponding subpixel among the plurality of subpixels through a second gate line;
a light emission control driving circuit configured to supply the first light emission control signal and the second light emission control signal; and
a switching circuit configured to:
supply the first light emission control signal to a corresponding subpixel among the plurality of subpixels through a third gate line in response to the first viewing angle control signal, and
supply the second light emission control signal to a corresponding subpixel among the plurality of subpixels through a fourth gate line in response to the second viewing angle control signal.

7. The display apparatus of claim 1,
wherein the gate driving circuit includes:
a first switching circuit configured to selectively output a 1-1 light emission control signal and a 1-2 light emission control signal to the first display area in response to a 1-1 viewing angle control signal and a 1-2 viewing angle control signal, and
a second switching circuit configured to selectively output a 2-1 light emission control signal and a 2-2 light emission control signal to the second display area in response to a 2-1 viewing angle control signal and a 2-2 viewing angle control signal.

8. The display apparatus of claim 1, wherein each of the plurality of subpixels includes a pixel circuit time-divisionally driving the first light emitting element and the second light emitting element, the pixel circuit comprising:
a first capacitor connected between a gate electrode of the driving transistor and a second electrode of a first switching transistor;
the first switching transistor connecting a data line to a first electrode of the first capacitor in response to a first scan signal of a first gate line;
a second switching transistor connecting the gate electrode of the driving transistor and a second electrode of the driving transistor in response to a second scan signal of a second gate line;
the first light emission control transistor connecting the driving transistor to the first light emitting element during a light emitting period within a driving period of a first viewing angle mode in response to the first light emission control signal of a third gate line; and
the second light emission control transistor connecting the driving transistor to the second light emitting element during the light emitting period within the driving period of a second viewing angle mode in response to the second light emission control signal of a fourth gate line.

9. The display apparatus of claim 8, wherein the pixel circuit further comprises:
a third switching transistor connecting a reference line to the first electrode of the first capacitor during the driving period of the first viewing angle mode in response to the first light emission control signal of the third gate line, and
a fourth switching transistor connecting the reference line to the first electrode of the first capacitor during the driving period of the second viewing angle mode in response to the second light emission control signal of the fourth gate line.

10. The display apparatus of claim 9, wherein the pixel circuit further comprises:
a 5-1 switching transistor connecting the reference line to an anode electrode of the first light emitting element in response to the second scan signal of the second gate line; and
a 5-2 switching transistor connecting the reference line to an anode electrode of the second light emitting element in response to the second scan signal of the second gate line.

11. The display apparatus of claim 8, further comprising:
a second capacitor connected between a high-potential power line and the gate electrode of the driving transistor.

12. A display apparatus, comprising:
a first display area including a first subpixel, wherein the first subpixel includes:
a first light emitting element emitting light of a first color;
a first lens of a first shape overlapping the first light emitting element in a cross-sectional view of the display apparatus;
a second light emitting element emitting light of the first color; and
a second lens of a second shape overlapping the second light emitting element in the cross-sectional view; and
a second display area including a second subpixel, wherein the second subpixel includes:
a third light emitting element emitting light of the first color;
a third lens of the first shape overlapping the third light emitting element in the cross-sectional view;
a fourth light emitting element emitting light of the first color; and
a fourth lens of the second shape overlapping the fourth light emitting element in the cross-sectional view,
wherein the first light emitting element is in a first state and the second light emitting element is in a second state, when the first display area is in a first mode,
wherein the first light emitting element is in the second state and the second light emitting element is in the first state, when the first display area is in a second mode,
wherein the third light emitting element is in the first state and the fourth light emitting element is in the second state, when the second display area is in the first mode, and
wherein the third light emitting element is in the second state and the fourth light emitting element is in the first state, when the second display area is in the second mode.

13. The display apparatus of claim 12, wherein the first display area emits light over a first viewing angle in a first direction, when the first display area is in the first mode,
wherein the first display area emits light over a second viewing angle in the first direction that is less than the first viewing angle, when the first display area is in the second mode,
wherein the second display area emits light over the first viewing angle in the first direction, when the second display area is in the first mode, and
wherein the second display area emits light over the second viewing angle in the first direction, when the second display area is in the second mode.

14. The display apparatus of claim 13, wherein a length of the first lens along the first direction is greater than a length of the second lens along the first direction, and
wherein a length of the third lens along the first direction is greater than a length of the fourth lens along the first direction.

15. The display apparatus of claim 13, wherein the first lens transmits light over the first viewing angle in the first direction, when the first display area is in the first mode,
wherein the second lens transmits light over the second viewing angle in the first direction, when the first display area is in the second mode,
wherein the third lens transmits light over the first viewing angle in the first direction, when the second display area is in the first mode, and
wherein the fourth lens transmits light over the second viewing angle in the first direction, when the second display area is in the second mode.

16. The display apparatus of claim 12, wherein the first light emitting element is in the first state in response to a first control signal having a predetermined value,
wherein the second light emitting element is in the first state in response to a second control signal having the predetermined value,
wherein the third light emitting element is in the first state in response to a third control signal having the predetermined value, and
wherein the fourth light emitting element is in the first state in response to a fourth control signal having the predetermined value.

17. The display apparatus of claim 16, wherein a first light emission control transistor of the first subpixel connects the first light emitting element with a driving transistor of the first subpixel in response to the first control signal having the predetermined value,
wherein a second light emission control transistor of the first subpixel connects the second light emitting element with the driving transistor of the first subpixel in response to the second control signal having the predetermined value,
wherein a first light emission control transistor of the second subpixel connects the third light emitting element with a driving transistor of the second subpixel in response to the third control signal having the predetermined value, and
wherein a second light emission control transistor of the second subpixel connects the fourth light emitting element with the driving transistor of the second subpixel in response to the fourth control signal having the predetermined value.

18. The display apparatus of claim 17, further comprising:
a first switching circuit configured to output a first emission signal having the predetermined value to the first display area in response to the first control signal having the predetermined value, wherein the first switching circuit is configured to further output a second emission signal having the predetermined value to the first display area in response to the second control signal having the predetermined value; and
a second switching circuit configured to output a third emission signal having the predetermined value to the second display area in response to the third control signal having the predetermined value, wherein the second switching circuit is configured to further output a fourth emission signal having the predetermined value to the second display area in response to the fourth control signal having the predetermined value.

19. The display apparatus of claim 18, wherein, responsive to the first control signal having the predetermined value and the first emission signal having the predetermined value, a first switching transistor of the first switching circuit is configured to activate the first light emission control transistor of the first subpixel connecting the first light emitting element with the driving transistor of the first subpixel,
wherein, responsive to the second control signal having the predetermined value and the second emission signal having the predetermined value, a second switching transistor of the first switching circuit is configured to activate the second light emission control transistor of the first subpixel connecting the second light emitting element with the driving transistor of the first subpixel,
wherein, responsive the third control signal having the predetermined value and the third emission signal having the predetermined value, a first switching transistor of the second switching circuit is configured to activate the first light emission control transistor of the second subpixel connecting the third light emitting element with the driving transistor of the second subpixel, and
wherein, responsive to the fourth control signal having the predetermined value and the fourth emission signal having the predetermined value, a second switching transistor of the second switching circuit is configured to activate the second light emission control transistor of the second subpixel connecting the fourth light emitting element with the driving transistor of the second subpixel.

20. The display apparatus of claim 18, further comprising:
a light emission control driving circuit configured to output a first light emission control signal to the first switching circuit and a second light emission control signal to the second switching circuit,
wherein the first switching circuit is configured to output the first light emission control signal to the first display area as the first emission signal in response to the first control signal having the predetermined value,
wherein the first switching circuit is configured to output the first light emission control signal to the first display area as the second emission signal in response to the second control signal having the predetermined value,
wherein the second switching circuit is configured to output the second light emission control signal to the second display area as the third emission signal in response to the third control signal having the predetermined value, and
wherein the second switching circuit is configured to output the second light emission control signal to the second display area as the fourth emission signal in response to the fourth control signal having the predetermined value.
